(19) United States
(12) Patent Application Publication
(10) Pub. No.: US 2014/0144494 A1
(43) Pub. Date: May 29, 2014

(54) SOLAR CELL

(71) Applicant: Samsung SDI Co., Ltd., Yongin-si (KR)

(72) Inventor: Hyun-Jong Kim, Yongin-si (KR)

(73) Assignee: Samsung SDI Co., Ltd., Yongin-si (KR)

(21) Appl. No.: 14/033,406

(22) Filed: Sep. 20, 2013

Related U.S. Application Data
(60) Provisional application No. 61/729,513, filed on Nov. 23, 2012.
(60) Provisional application No. 61/751,219, filed on Jan. 10, 2013.

(51) Int. Cl. H01L 31/065; H01L 31/18

(52) U.S. Cl. CPC H01L 31/065; H01L 31/18
USPC 136/255; 438/85

(57) ABSTRACT

The present invention relates to a solar cell layer and a method of making the same. The solar cell includes a substrate, a rear electrode layer on the substrate, a light absorbing layer on the rear electrode layer, a buffer layer on the light absorbing layer, a transparent electrode layer on the buffer layer, and an anti-reflection layer on the transparent electrode. The light absorbing layer has a first region having a graded bandgap energy profile, a second region having a graded bandgap energy profile, and third region, between the first region and the second region, having a substantially flat bandgap energy profile. Such bandgap energy profiles allows for easy excitation of the valence band into the conduction band, while also preventing electrons and holes from combining in the light absorbing layer, thus increasing efficiency of the solar cell.

### CROSS-REFERENCE TO RELATED APPLICATION

This application claims priority to and the benefit of U.S. Provisional Application No. 61/729,513, filed on Nov. 23, 2012, and U.S. Provisional Application No. 61/751,219, filed on Jan. 10, 2013. The entire contents of both of these provisional applications are incorporated herein by reference. In addition, the present application incorporates herein by reference the entire content of U.S. patent application Ser. No. ______, Attorney Docket No. 72190/S744, filed on even date herewith.

### BACKGROUND

1. Field

The present invention relates to a solar cell, and more particularly, to a rear electrode solar cell.

2. Description of the Related Art

Recently, depletion of energy resources and problems regarding the environment of the Earth accelerate development of clean energies. From among various kinds of clean energies, solar power energy generation (using solar cells) directly converts solar light to electricity, and is thus being focused on as a new energy source.

However, costs for power generation using current industrial solar cells are still relatively high as compared to thermal power generation. For wide application of solar cells, it is necessary to improve power generating efficiency of solar cells.

### SUMMARY

Aspects of embodiments of the present disclosure are directed toward a solar cell having improved power generating efficiency and a method of making the same.

In an embodiment, a solar cell is provided. The solar cell includes a substrate, a first electrode layer on the substrate, a light absorbing layer on the first electrode layer, and a buffer layer on the light absorbing layer. The light absorbing layer includes a first region having a graded bandgap energy profile, a second region having a graded bandgap energy profile, and a third region, between the first region and the second region, having a substantially flat bandgap energy profile.

In one embodiment, the solar cell further includes a second electrode layer on the buffer layer.

In one embodiment, the second electrode layer is a transparent electrode.

In one embodiment, the solar cell further includes an anti-reflection layer on the second electrode layer.

In one embodiment, the graded bandgap energy profile of the first region increases toward an interface between the first electrode layer and the light absorbing layer.

In one embodiment, the graded bandgap energy profile of the second region increases toward an interface between the light absorbing layer and the buffer layer.

In one embodiment, the graded bandgap energy profile of the first region and the graded bandgap energy profile of the second region meet the substantially flat bandgap energy profile of the third region at respective minima of the graded bandgap energy profiles.

In one embodiment, the substantially flat bandgap energy profile of the third region is, on average, lower than the graded bandgap energy profile of the first region and the graded bandgap energy profile of the second region.

In one embodiment, the difference between a highest bandgap energy and a lowest bandgap energy of the substantially flat bandgap energy profile in the third region is less than or equal to 0.2 eV.

In one embodiment, the light absorbing layer includes at least one of a Group III atom and a Group VI atom.

In one embodiment, the Group III atom includes at least one of Ga and In, and the Group VI atom includes at least one of S and Se.

In one embodiment, a bandgap energy of the light absorbing layer varies according to a concentration distribution of at least one of the Group III atom and the Group VI atom, in the light absorbing layer.

In one embodiment, a concentration the Group VI atom is higher in the first region and in the second region than in the third region of the light absorbing layer.

In one embodiment, a concentration of the Group III atom varies by less than 10%, throughout the light absorbing layer.

In one embodiment, the light absorbing layer includes a compound of chemical formula Cu(InₓGa₁₋ₓ)(Se_{y}S_{1-y).}

In another embodiment, a method of preparing a solar cell is provided. The method includes forming a first electrode on a substrate, forming a light absorbing layer on the first electrode, and forming a buffer layer on the light absorbing layer. The forming of the light absorbing layer includes forming a precursor layer on the first electrode, the precursor layer including Cu, Ga, and In, performing a first heat treatment on the precursor layer with a Se-containing gas to form a Cu(InₓGa₁₋ₓ)Se₂ layer, and performing a second heat treatment on the Cu(InₓGa₁₋ₓ)Se₂ layer with a S-containing gas to form a Cu(InₓGa₁₋ₓ)(Se_{y}S_{1-y}) layer, to provide the light absorbing layer.

In one embodiment, the method further includes forming a second electrode layer on the buffer layer.

In one embodiment, the method further includes forming an anti-reflection layer on the second electrode layer.

In one embodiment, the forming of the precursor layer includes forming a Cu—Ga—In layer on the first electrode layer.

In one embodiment, the forming of the precursor layer includes forming a Cu—Ga layer on the first electrode layer and then forming an In layer on the Cu—Ga layer.

In one embodiment, the forming of the precursor layer includes sputtering with a Cu—Ga—In alloy as a target material.

In one embodiment, the forming of the precursor layer includes sputtering with a Cu—Ga alloy as a target material and sputtering with an In-based material as a target material.

In one embodiment, the first heat treatment is performed at a temperature from about 300° C. to about 500° C. for a period of time from about 5 minutes to about 40 minutes.

In one embodiment, the second heat treatment is performed at a temperature from about 500° C. to about 700° C. for a period of time from about 10 minutes to about 100 minutes.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is a schematic sectional view of a solar cell according to an embodiment of the present invention.

FIG. 2 is a diagram showing bandgap energy distribution (bandgap energy profile) in a light absorbing layer according to an embodiment of the present invention in the solar cell of FIG. 1.

FIG. 3 shows concentration interval distribution of Ga atoms for two examples (A′ and B′), according to depths of a light absorbing layer having the bandgap energy distribution (bandgap energy profile) of FIG. 2.

FIG. 4 shows concentration interval distribution of S atoms according to depths of a light absorbing layer having the bandgap energy distribution of FIG. 2.

FIG. 5 shows a bandgap energy profile according to a change in Ga concentration for two examples (A′ and B′).

FIG. 6 is a graph showing a short-circuit current multiplied by open circuit voltage of a solar cell in sunlight according to an embodiment of the present invention.

FIGS. 7 through 13 are schematic sectional views showing a method of manufacturing a solar cell according to an embodiment of the present invention.

### DETAILED DESCRIPTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided by way of example to. The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise”, “comprises” and/or “comprising”, when used in this specification, specify the presence of stated features, integers, steps, operations, elements, and/or components, but do not preclude the presence of an additional one or more other features, integers, steps, operations, elements, components, and/or groups thereof. It will be understood that although the terms first and second are used herein to describe various elements, these elements should not be limited by these terms. Like numbers refer to like elements throughout.

In the drawings, the thicknesses of layers and regions are exaggerated for clarity. It will be understood that when a layer is referred to as being “on” another layer or substrate, it can be directly on the other layer or substrate, or intervening layers may also be present. However, when a layer is referred to as being “directly on” another layer or substrate, no intervening layer is present.

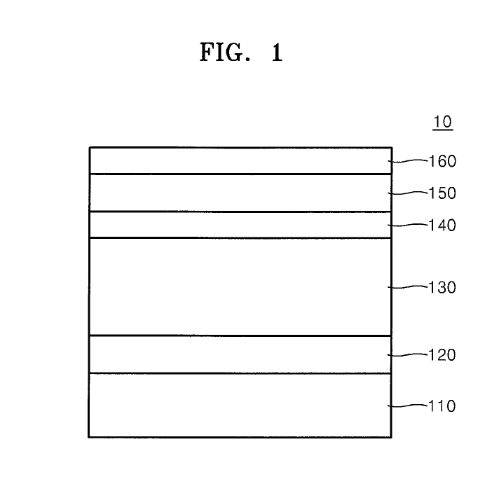

FIG. 1 is a schematic sectional view of a solar cell 10 according to an embodiment of the present invention.

Referring to FIG. 1, the solar cell 10 is a rear electrode solar cell and includes a light absorbing layer 130, which is formed to have a double graded bandgap energy having different grades, and a substantially flat bandgap energy profile between the double graded bandgap energy profile. In particular, the light absorbing layer 130 includes a first region having a graded bandgap energy profile, a second region having a graded bandgap energy profile, and a third region, between the first region and the second region, having a substantially flat bandgap energy profile.

In more detail, the solar cell 10 includes a substrate 110, a rear electrode layer 120 formed on the substrate 110, the light absorbing layer 130 formed on the rear electrode layer 120, a buffer layer 140 formed on the light absorbing layer 130, and a transparent electrode layer 150 formed on the buffer layer 140.

The substrate 110 used in the solar cell 10 may be a glass substrate or a polymer substrate having suitable phototransmissivity. For example, the glass substrate may be formed of soda-lime glass or high strained point soda glass, and the polymer substrate may be formed of polyimide. However, the present invention is not limited thereto. The glass substrate may be formed of low iron tempered glass to protect devices therein from external shocks and to improve transmittance of solar light. Particularly, since low iron soda-lime glass releases sodium (Na) ions at a process temperature over 500° C., the low iron soda-lime glass may further improve efficiency of the light absorbing layer 130. The substrate 110 may be formed of a ceramic, such as alumina, stainless steel, or a flexible polymer.

The rear electrode layer 120 may be formed of a metal having suitable conductivity and light reflectivity, such as molybdenum (Mo), aluminium (Al), or copper (Cu), to collect charges formed via the photovoltaic effect and to reflect light transmitted through the light absorbing layer 130, such that the light is re-absorbed by the light absorbing layer 130.

Particularly, the rear electrode layer 120 may contain Mo in consideration of its high conductivity, its ohmic contact with the light absorbing layer 130, and its high temperature stability in a selenium (Se) or sulphur (S) atmosphere associated with formation of the light absorbing layer 130. The rear electrode layer 120 may have a thickness from about 200 nm to about 500 nm.

The rear electrode layer 120 may be doped with alkali ions, such as Na ions. During growth of the light absorbing layer 130, alkali ions of the rear electrode layer 120 are mixed into the light absorbing layer 130 and may provide the light absorbing layer 130 with structural advantages and/or improve conductivity of the light absorbing layer 130. Therefore, open circuit voltage V_{OC} of the solar cell 10 increases and thus efficiency of the solar cell 10 may be improved.

The rear electrode layer 120 may be formed in a multi-layer to provide suitable adherence to the substrate 110 and to provide a suitable resistance characteristic of the rear electrode layer 120.

The light absorbing layer 130 according to an embodiment of the present invention absorbs solar light incident on the solar cell 10. The light absorbing layer 130 according to an embodiment of the present invention may include quinary compound of Cu—In—Ga—Se—S with a chemical formula of Cu(InₓGa₁₋ₓ)(Se_{y}S_{1-y}). In an embodiment of the present invention in the crystal lattice structure of the Cu(InₓGa₁₋ₓ)(Se_{y}S_{1-y}) compound, In is partially replaced by Ga and Se is partially replaced by S. In an embodiment of the present invention x is 0.01≦x≦0.25, and y is 0.1≦y≦0.30. In an embodiment of the present invention, Ga has a grade towards the rear electrode layer. In an embodiment of the present invention the Ga concentration may differ by less than 10% throughout the light absorbing layer, optionally the Ga concentration may differ by less than 10% throughout the light absorbing layer, optionally the Ga concentration may differ by less than 5% throughout the light absorbing layer. In an embodiment of the present invention the Ga concentration may vary between 0.5% and 10%, optionally between 2% and 5%.

In an embodiment of the present invention the light absorbing layer has a first and a second maximal S concentration, the first maximal S concentration being towards the interface with the rear electrode layer and the second maximal S concentration being towards the interface with the buffer layer, optionally wherein the universal minima concentration of S is between the first and second maximal S concentrations. In an embodiment of the present invention, the S concentration may be represented by a S/(Se+S) mole ratio. In an embodiment of the present invention the first and the second maximal S concentration are independently preferably from about 0.30 to about 0.50, preferably about 0.32 to about 0.45. In an embodiment of the present invention the universal minima concentration of S is represented by a S/(Se+S) mole ratio of from about 0.02 to about 0.12, preferably about 0.05 to about 0.10.

In an embodiment, a layer 131, to be converted to the light absorbing layer 130, is formed of a copper-indium-gallium-selenide (Cu(In, Ga)Se₂, CIGS) based compound containing copper (Cu), indium (In), gallium (Ga), and selenium (Se), and forms a p type semiconductor layer.

In an embodiment, the layer 131 is formed of a quaternary compound and has a chemical formula Cu(InₓGa1₋ₓ)Se₂. In the crystal lattice structure of the compound, Ga partially replaces In.

Such a CIGS compound is referred to as chalcopyrite compound and has properties of a p type semiconductor. A CIGS compound semiconductor has a direct transition bandgap energy.

In an embodiment, the light absorbing layer 130 is a quinary compound of Cu—In—Ga—Se—S, where chemical formula thereof is Cu(InₓGa₁₋ₓ)(Se_{y}S_{1-y}). Here, in the crystal lattice structure of the Cu(InₓGa₁₋ₓ)(Se_{y}S_{1-y}) compound, In is partially replaced by Ga and Se is partially replaced by S.

In an embodiment, the light absorbing layer 130 has a double graded bandgap energy profile having different grades and a substantially flat bandgap energy profile between the double graded bandgap energy profile, thereby improving efficiency of the solar cell 10. In an embodiment of the present invention, in the flat bandgap energy profile the difference between the largest bandgap energy and the lowest bandgap energy in the flat bandgap energy profile is less than or equal to 0.2 eV, optionally less than or equal to 0.1 eV or less than or equal to 0.04 eV. In an embodiment of the present invention, the difference between the largest bandgap energy and the lowest bandgap energy in the flat bandgap energy profile is from 0.0 eV to 0.2 eV, optionally 0.005 eV to 0.1 eV, optionally from 0.01 eV to 0.04 eV.

In an embodiment of the present invention, the light absorbing layer has a first and a second graded region on either side of the flat bandgap energy profile, wherein: the first graded region has a graded bandgap energy profile that increases toward the interface between the rear electrode layer and the light absorbing layer; and the second graded region has a bandgap energy profile that increases in a direction from the flat bandgap energy profile toward the interface between the light absorbing layer and the buffer layer.

In an embodiment of the present invention, the graded bandgap energy profiles are adjusted to decrease toward the flat bandgap energy profile, optionally wherein the flat bandgap energy profile comprises the universal minimum bandgap energy.

In particular, in an embodiment, the light absorbing layer 130 includes (e.g. along a direction from the rear electrode layer 120 to the buffer layer 140) a first region having a graded bandgap energy profile, a second region having a graded bandgap energy profile, and a third region, between the first region and the second region, having a substantially flat bandgap energy profile. In some embodiments, a bandgap energy profile is linear. In other embodiments, a bandgap energy profile is non-linear.

In some embodiments, the graded bandgap energy profile of the first region and the graded bandgap energy profile of the second region meet the substantially flat bandgap energy profile of the third region at respective minima of the graded bandgap energy profiles.

In an embodiment, the buffer layer 140 reduces a difference between bandgap energies of the light absorbing layer 130 and the transparent electrode layer 150, and reduces recombination of electrons and holes that may occur between the light absorbing layer 130 and the transparent electrode layer 150. By way of example, the buffer layer 140 may be formed of CdS, ZnS, In₂S₃, and/or ZnₓMg₁₋ₓO. For example, if the buffer layer 140 is formed of CdS, a CdS thin-film is formed of a n-type semiconductor, where resistance thereof may be reduced by doping the CdS thin-film with In, Ga, and/or Al, for example.

The transparent electrode layer 150 may be formed of a material having high phototransmissivity, such that solar light may be transmitted to the light absorbing layer 130.

Furthermore, to function as an electrode layer, the transparent electrode layer 150 may be formed of a conductive material having a low resistance. The transparent electrode layer 150 may be formed of zinc oxide (ZnO) doped with boron (B), aluminium (Al) and/or indium tin oxide (ITO). ZnO doped with B and/or Al is suitable to be used as an electrode due to its low resistance. Particularly, ZnO doped with B increases transmittance of light of near-infrared ray domain, thereby increasing short-circuit current of a solar cell.

An anti-reflection layer 160 may be further formed on the transparent electrode layer 150. Efficiency of a solar cell may be improved by reducing reflection loss of solar light by forming the anti-reflection layer 160 on the transparent electrode layer 150. The anti-reflection layer 160 may be formed of MgF₂, for example.

The anti-reflection layer 160 may be textured to reduce reflection and increase absorption of solar light incident on the light absorbing layer 130.

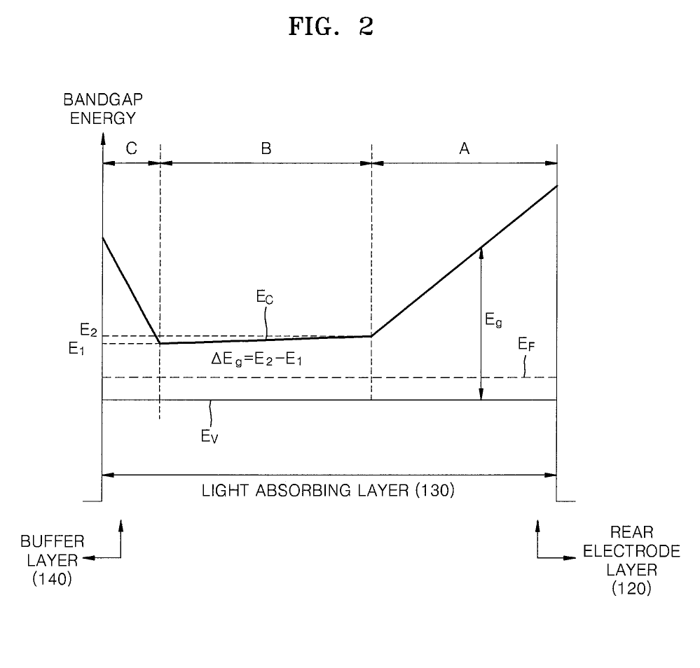

FIG. 2 is a diagram showing bandgap energy distribution (bandgap energy profile) in the light absorbing layer 130 according to an embodiment of the present invention in the solar cell 10 of FIG. 1.

Referring to FIGS. 1 and 2, E_{V} denotes valence energy band, whereas E_{C} denotes conduction energy band. Bandgap energy E_{g} refers to an energy gap between the conduction energy band E_{C} and the valence energy band E_{V}.

Bandgap energy E_{g} of the light absorbing layer 130 may be calculated by using E_{g} calculation equation. In other words, the bandgap energy E_{g} may be calculated by using E_{g} calculation equation based on Ga content and S content.

Generally, if bandgap energy E_{g} nearby the rear electrode layer 120 is large, electrons and holes in the light absorbing layer 130 may be prevented from being recombined, and thus efficiency of the solar cell 10 may be improved.

Furthermore, if bandgap energy E_{g} nearby the rear electrode layer 120 is large, the open circuit voltage V_{OC} of the solar cell 10 increases, and thus efficiency of the solar cell 10 is improved.

Here, the open circuit voltage V_{OC} refers to a difference between potentials formed at two opposite ends of the solar cell 10 when infinite impedance is applied to the solar cell 10 and light is incident to the solar cell 10. In other words, the open circuit voltage V_{OC} is the maximum current that may be obtained from the solar cell 10. Generally, if a current of open circuit is significantly smaller than that of a short circuit, the open circuit voltage V_{OC} is proportional to intensity of incident light.

Furthermore, if a p-n junction is formed properly, the higher the band-gap energy of a semiconductor, the greater the open circuit voltage Voc.

Therefore, if bandgap energy E_{g} at the interface between the light absorbing layer 130 and the rear electrode layer 120 increases, recombination of electrons and holes may be prevented and open circuit voltage V_{OC} may increase, and thus the overall efficiency of the solar cell 10 may be improved.

Referring to FIG. 2, a region A is a region of the light absorbing layer 130 which interfaces with the rear electrode layer 120. The light absorbing layer 130 has a graded bandgap energy, where bandgap energy increases toward the interface between the rear electrode layer 120 and the light absorbing layer 130.

Therefore, the region A has the largest band gap energy E_{g} at the interface between the rear electrode layer 120 and the light absorbing layer 130, and bandgap energy decreases in a direction from the rear electrode layer 120 to the light absorbing layer 130.

Region B is a region between the region A to the top surface of the light absorbing layer 130 and is an internal region of the light absorbing layer 130. The region B has a substantially flat bandgap energy profile. In some embodiments, the difference (ΔEg=E₂−E₁) between a largest bandgap energy E₂ and a lowest bandgap energy E₁ in the substantially flat bandgap energy profile of region B is less than or equal to 0.2 eV. In some embodiments, the difference (ΔEg=E₂−E₁) between the largest bandgap energy E₂ and the lowest bandgap energy E₁ in the substantially flat bandgap energy profile of region B is less than or equal to 0.1 eV. In some embodiments, the difference (ΔEg=E₂−E₁) between the largest bandgap energy E₂ and the lowest bandgap energy E₁ in the substantially flat bandgap energy profile of region B is less than or equal to 0.04 eV.

The bandgap energy profile of the region B is, on average, smaller than bandgap energy profile of region A and bandgap energy profile of region C.

The smaller the bandgap energy profile of region B is, the more efficient the photovoltaic effect may be. If region B has large bandgap energy, even if the light absorbing layer 130 receives solar light, it is not easy for electrons in the valence band to be excited to the conduction band. Therefore, the overall power generating efficiency of the solar cell 10 may be deteriorated.

Therefore, region A has graded bandgap energy that is adjusted to decrease toward the region B, and the region B has a minimized bandgap energy, and thus power generating efficiency of the solar cell 10 may be improved. However, efficiency of the solar cell 10 is not unconditionally proportional to a width of the substantially flat bandgap energy profile, and the width of bandgap energy profile of region B can be suitably adjusted for efficiency.

Region C is a region of the light absorbing layer 130 which interfaces with the buffer layer 140, which is an n-type semiconductor.

The region C has a graded bandgap energy profile, where bandgap energy increases in a direction from an internal region of the light absorbing layer 130 toward the interface between the light absorbing layer 130 and the buffer layer 140.

Therefore, bandgap energy increased in the region C may increase open circuit voltage, thereby improving efficiency of the solar cell 10.

The bandgap energy E_{g} distribution in the light absorbing layer 130 may be controlled by adjusting process conditions for forming the light absorbing layer 130 and contents of Ga and S.

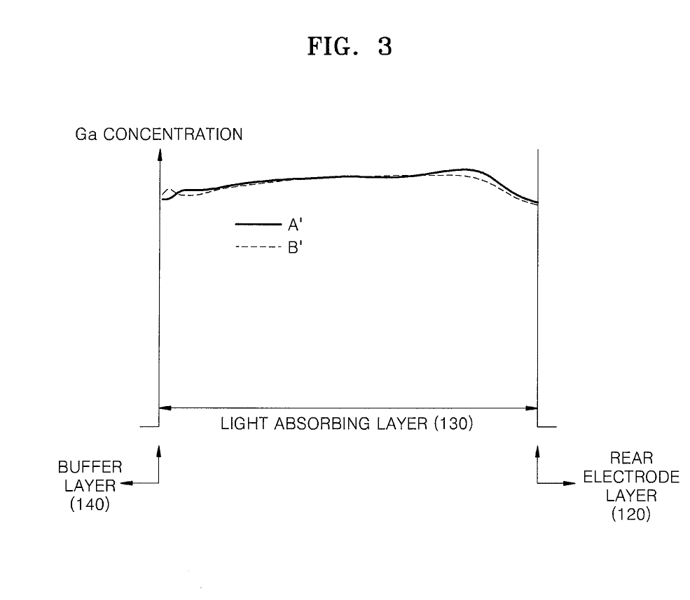

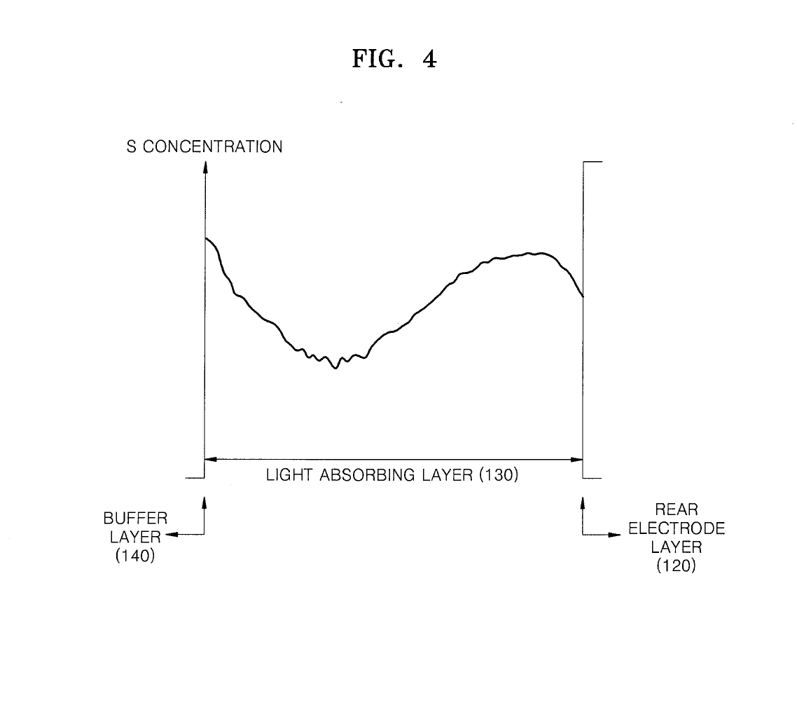

FIG. 3 shows concentration interval distributions of Ga atoms for two examples (A′ and B′) according to depths of a single light absorbing layer having the bandgap energy distribution (bandgap energy profile) of FIG. 2, and FIG. 4 shows a concentration interval distribution of S atoms according to depths of a light absorbing layer having the bandgap energy distribution (bandgap energy profile) of FIG. 2.

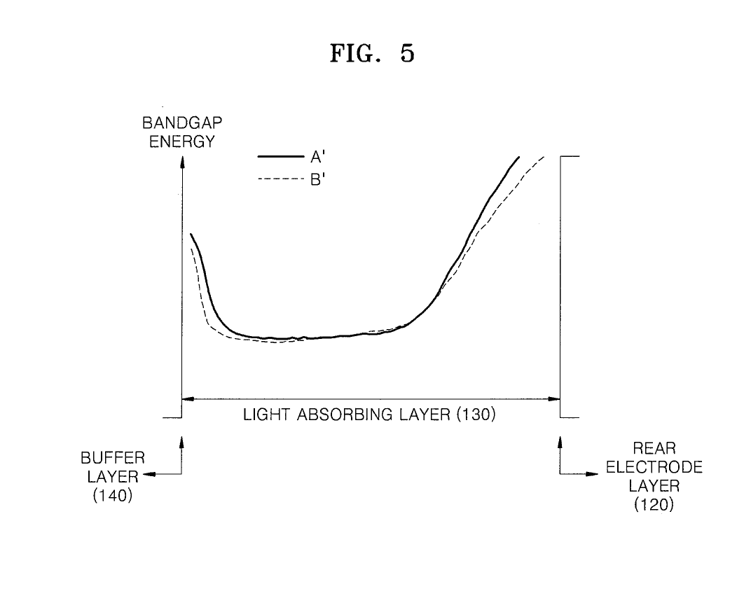

FIG. 5 shows bandgap energy profiles for two examples (A′ and B′) according to Ga concentration in the light absorbing layer shown in FIG. 3, according to another embodiment. Here, in one embodiment, Ga concentration varies by less than 10%, throughout the light absorbing layer. In another embodiment, Ga concentration varies by less than 5%, throughout the light absorbing layer.

In one embodiment (e.g. as shown in the flat bandgap energy region of FIG. 5), the difference (ΔEg=E₂−E₁) between a largest bandgap energy E₂ and a lowest bandgap energy E₁ is less than or equal to 0.2 eV. In some embodiments, the difference (ΔEg=E₂−E₁) between the largest bandgap energy E₂ and the lowest bandgap energy E₁ in the substantially flat bandgap energy profile is less than or equal to 0.1 eV. In some embodiments, the difference (ΔEg=E₂−E) between the largest bandgap energy E₂ and the lowest bandgap energy E₁ in the substantially flat bandgap energy profile is less than or equal to 0.04 eV.

Referring to FIGS. 3 and 4, region B having the substantially flat bandgap energy profile of FIG. 2 and regions A and C having the graded bandgap energy profiles, in which bandgap energies increase in opposite directions from two opposite sides of the region B toward the interface between the light absorbing layer 130 and the rear electrode layer 120, and the interface between the light absorbing layer 130 and the buffer layer 140, may be formed by controlling concentration profiles of Ga and S according to depth of the light absorbing layer 130.

Furthermore, although concentration distributions of Ga and S are used for forming the bandgap energy distribution (bandgap energy profile) of FIG. 2 in FIGS. 3 and 4, the present invention is not limited thereto, and a bandgap energy distribution (bandgap energy profile) in which a substantially flat region is formed in the region B of FIG. 2 may be formed by using different types of concentration profiles.

Furthermore, if the light absorbing layer 130 is formed of a Group III atom and a Group VI atom other than Ga and S, the bandgap energy distribution (bandgap energy profile) of FIG. 2 may be formed by using concentration profiles of the Group III atom and the Group VI atom other than Ga and S.

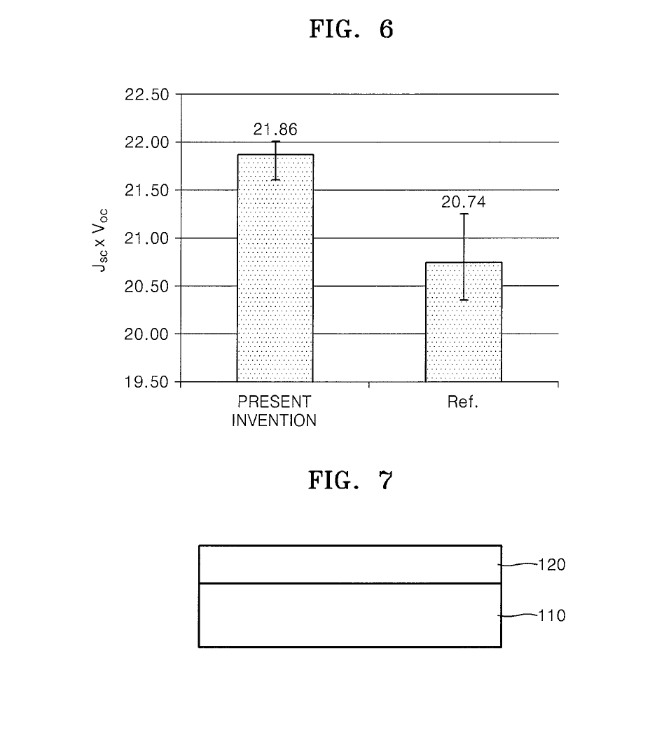

FIG. 6 is a graph showing a short-circuit current J_{SC} multiplied by open circuit voltage V_{OC} of a solar cell in sunlight according to an embodiment of the present invention. J_{SC}V_{OC}, which is the multiplication of the short-circuit current by the open circuit voltage, is proportional to efficiency of the solar cell. Therefore, efficiency of the solar cell increases as J_{SC}V_{OC} increases.

Referring to FIG. 6, the case in which a substantially flat band gap energy B exists between the double graded bandgap energies A and C (FIG. 2) features a larger J_{SC}V_{OC} value than a case (Ref.) in which only double graded bandgap energies exist, where an average of multiplication of open circuit voltages V_{OC} (mV) by short-circuit currents J_{SC} (mA/cm²) is 21.86.

In other words, according to an embodiment of the present invention, since the light absorbing layer 130, in which a substantially flat bandgap energy profile of region B (referring to FIG. 2) exists between double graded bandgap energies of regions A and C (referring to FIG. 2) having different grades, is employed, thereby increasing J_{SC}V_{OC}. As a result, efficiency of a solar cell may be improved.

FIGS. 7 through 13 are schematic sectional views showing a method of manufacturing a solar cell according to an embodiment of the present invention. In an embodiment of the present invention, provided is a process for producing the above-defined solar cells comprising the following ordered steps:

(a) the rear electrode layer is formed on the substrate, optionally wherein the rear electrode layer is formed of Mo;

(b) forming a precursor layer on the rear electrode layer by:
(i) forming a Cu—Ga—In layer on the rear electrode layer; or
(ii) forming a Cu—Ga layer on the rear electrode layer and forming an In layer on the Cu—Ga layer;

(c) performing a first heat treatment with a Se-containing gas on the precursor layer including either the Cu—Ga—In layer or the Cu—Ga layer and the In layer to form a layer formed of Cu(InₓGa₁₋ₓ)Se₂;

(d) performing a second heat treatment on the first light absorbing layer with a S-containing gas to form the second light absorbing layer formed of Cu(InₓGa₁₋ₓ)(Se_{y}S_{1-y}) as the light absorbing layer;

(e) forming a buffer layer on the second light absorbing layer; and

(f) forming a transparent electrode layer on the buffer layer.

In various embodiments of the present invention, the following process steps are preferably included:

(i) in step (a), the rear electrode layer is formed by DC sputtering using a Mo target or by chemical vapor deposition (CVD); and/or

(ii) in step (b)(i), the precursor layer made of Cu—Ga—In is formed via sputtering by using Cu—Ga—In alloy as a target material; and/or

(iii) in step (b)(ii), the precursor layer is formed via DC sputtering by using a Cu—Ga alloy as a target material, followed by sputtering using an In-based material as a target material; and/or

(iv) in step (c), the first heat treatment is performed in a vacuum chamber, where the Se-containing gas is a mixed gas including an inert gas and hydrogen selenide (H₂Se) gas, optionally wherein the first heat treatment is performed at a temperature from about 300° C. to about 500° C. for a period of time from about 5 minutes to about 40 minutes; and/or

(v) in step (d), the second heat treatment is performed in a vacuum chamber, where the S-containing gas is a mixed gas including an inert gas and hydrogen sulfide (H₂S) gas, optionally wherein the second heat treatment is performed at a temperature from about 500° C. to about 700° C. for a period of time from about 10 minutes to about 100 minutes; and/or

(vi) in step (e), the buffer layer comprises a CdS based material via chemical bath deposition (CBD); and/or

(vii) in step (f), the transparent electrode layer comprises ZnO and is formed via RF sputtering by using ZnO as a target material, reactive sputtering by using Zn as a target material, or metal organic chemical vapor deposition (MOCVD).

Referring to FIG. 6, the rear electrode layer 120 is formed on the substrate 110. As described above, the rear electrode layer 120 may be formed of Mo, which is a material which can satisfy the overall demands of the rear electrode layer 120. The rear electrode layer 120 may be formed by DC sputtering using a Mo target. Furthermore, the rear electrode layer 120 may be formed via chemical vapor deposition (CVD).

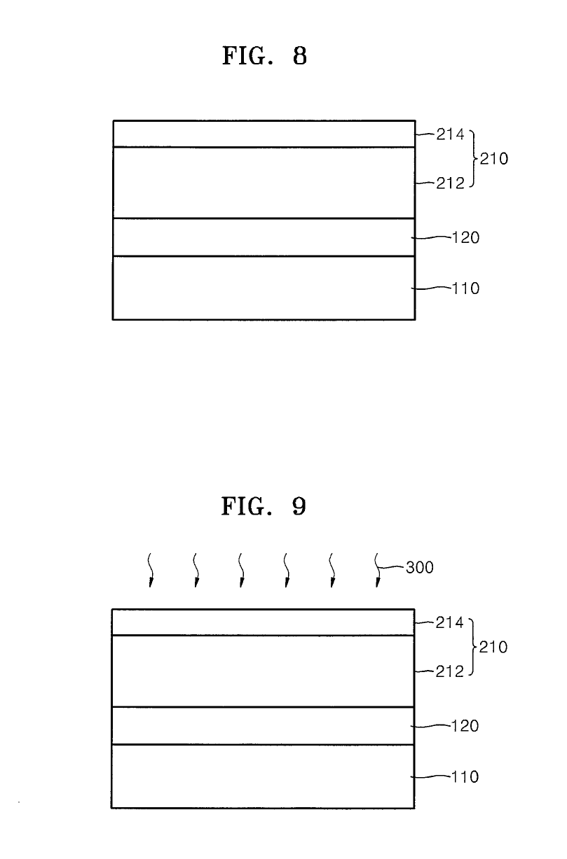

Referring to FIG. 8, a Cu—Ga layer 212 is formed on the rear electrode layer 120. Here, the Cu—Ga layer 212 may be formed via DC sputtering by using Cu—Ga alloy as a target material. Here, since Ga is a material that is typically not a target material by itself, the Cu—Ga alloy may be used as a target material.

Next, an In layer 214 is formed on the Cu—Ga layer 212. The In layer 214 may be formed via sputtering by using an In-based material as a target material.

Accordingly, a precursor layer 210 including the Cu—Ga layer 212 and the In layer 214 is formed on the rear electrode layer 120. Here, although the precursor layer 210 may be formed via a two-stage operation as described above, the precursor layer 210 may also be formed via sputtering by using Cu—Ga—In alloy as a target material. In this case, the precursor layer 210 is formed as a Cu—Ga—In layer.

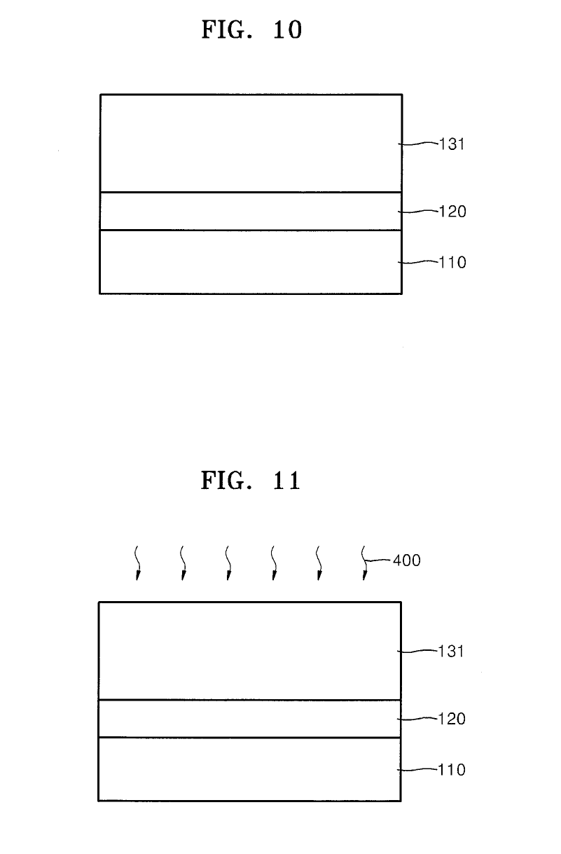

Referring to FIGS. 9 and 10, a layer 131, formed of Cu(InₓGa₁₋ₓ)Se₂, is formed by performing first heat treatment to the precursor layer 210 including the Cu—Ga layer 212 and the In layer 214 by using a Se-containing gas 300.

The first heat treatment is performed in a vacuum chamber, where the Se-containing gas 300 may be a mixed gas including an inert gas and hydrogen selenide (H₂Se) gas.

Furthermore, the first heat treatment may be performed at a temperature from about 300° C. to about 500° C. for a period of time from about 5 minutes to about 40 minutes.

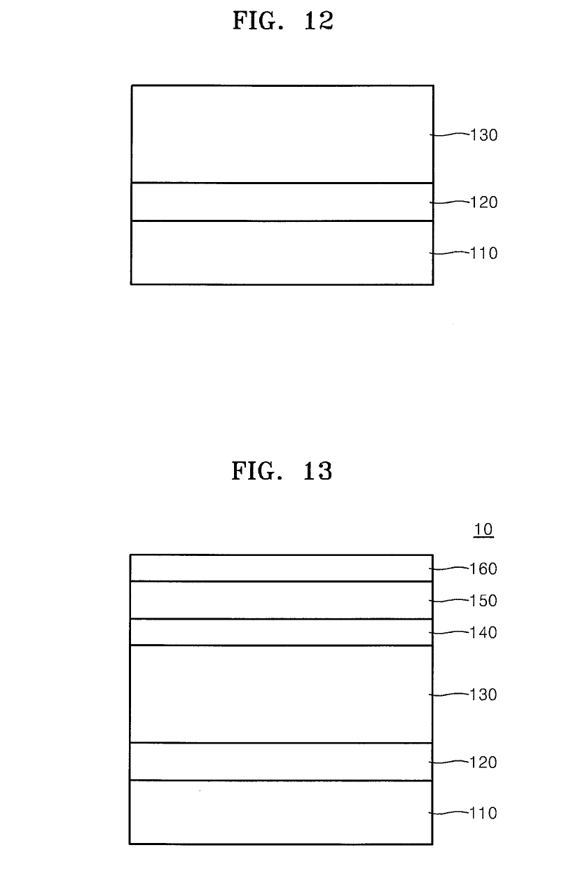

Referring to FIGS. 11 and 12, a second heat treatment is performed on the first light absorbing layer 131 by using a S-containing gas 400, thereby forming the light absorbing layer 130 formed of Cu(InₓGa₁₋ₓ)(Se_{y}S_{1-y}) on the first light absorbing layer 131. Furthermore, during the second heat treatment, temperature, time, and concentrations of S-containing gas may be controlled, such that S content in the first light absorbing layer 131 increases toward the rear electrode layer 120 as shown in FIG. 4.

The second heat treatment is performed in a vacuum chamber, where the S-containing gas 400 may be a mixed gas including an inert gas and hydrogen sulfide (H₂S) gas.

Furthermore, the second heat treatment may be performed at a temperature from about 500° C. to about 700° C. for a period of time from about 10 minutes to about 100 minutes, preferably about 500° C. to about 600° C. for 25 minutes to about 80 minutes, optionally about 30 minutes to about 70 minutes and optionally about 30 minutes to about 60 minutes for sulfurization, preferably the sulfurization step is carried out at a temperature of from about 525° C. to about 575° C., optionally from about 540° C. to about 560° C.

Layer 131 as described above, is converted into the light absorbing layer 130 of a solar cell according to an embodiment of the present invention.

Furthermore, temperatures, times, and concentrations of H₂Se and H₂S may controlled to form the light absorbing layer 130 having the bandgap energy distribution (bandgap energy profile) as shown in FIG. 2.

Referring to FIG. 13, the buffer layer 140 is formed on the light absorbing layer 130. The buffer layer 140 may be formed mainly of a CdS based material via chemical bath deposition (CBD).

Next, the transparent electrode layer 150 is formed on the buffer layer 140. The transparent electrode layer 150 may be formed mainly of ZnO. Therefore, the transparent electrode layer 150 may be formed via RF sputtering by using ZnO as a target material, reactive sputtering by using Zn as a target material, or metal organic chemical vapor deposition (MOCVD).

Next, an anti-reflection layer 160 may be formed on the transparent electrode layer 150. The anti-reflection layer may be formed via an electron beam evaporation using MgF₂.

According to embodiments of the present invention, the light absorbing layer 130 having double graded bandgap energies having different grades and a substantially flat bandgap energy profile therebetween as shown in FIG. 2 may be formed.

Therefore, at the interface between the light absorbing layer 130 and the rear electrode layer 120 and the interface between the light absorbing layer 130 and the buffer layer 140, high bandgap energies may be formed, thereby increasing open circuit voltage. Furthermore, since a bandgap energy profile of a set portion of the light absorbing layer 130 between the interface of the light absorbing layer 130 and the rear electrode layer 120 and the interface of the light absorbing layer 130 and the buffer layer 140, is substantially flat, power generating efficiency of a solar cell may be improved.

While the present invention has been particularly shown and described with reference to embodiments thereof, it is to be understood that the invention is not limited to the disclosed embodiments, but, on the contrary, is intended to cover various modifications and equivalent arrangements included within the spirit and scope of the appended claims, and equivalents thereof. It will be understood by those of ordinary skill in the art that various changes in form and details may be made therein without departing from the spirit and scope of the present invention.

What is claimed is:

1. A solar cell, comprising:
a substrate;
a first electrode layer on the substrate;
a light absorbing layer on the first electrode layer; and
a buffer layer on the light absorbing layer,
wherein the light absorbing layer comprises:
a first region having a graded bandgap energy profile,
a second region having a graded bandgap energy profile, and
a third region, between the first region and the second region, having a substantially flat bandgap energy profile.

2. The solar cell according to claim 1, further comprising a second electrode layer on the buffer layer, wherein the second electrode layer is a transparent electrode.

3. The solar cell according to claim 2, further comprising an anti-reflection layer on the second electrode layer.

4. The solar cell according to claim 1, wherein the graded bandgap energy profile of the first region increases toward an interface between the first electrode layer and the light absorbing layer.

5. The solar cell according to claim 1, wherein the graded bandgap energy profile of the second region increases toward an interface between the light absorbing layer and the buffer layer.

6. The solar cell according to claim 1, wherein the graded bandgap energy profile of the first region and the graded bandgap energy profile of the second region meet the substantially flat bandgap energy profile of the third region at respective minima of the graded bandgap energy profiles.

7. The solar cell according to claim 1, wherein the substantially flat bandgap energy profile of the third region is, on average, lower than the graded bandgap energy profile of the first region and the graded bandgap energy profile of the second region.

8. The solar cell according to claim 1, wherein the difference between a highest bandgap energy and a lowest bandgap energy of the substantially flat bandgap energy profile in the third region is less than or equal to 0.2 eV.

9. The solar cell according to claim 1, wherein the light absorbing layer comprises at least one of a Group III atom and a Group VI atom.

10. The solar cell according to claim 9, wherein the Group III atom comprises at least one of Ga and In, and wherein the Group VI atom comprises at least one of S and Se.

11. The solar cell according to claim 9, wherein a bandgap energy of the light absorbing layer varies according to a concentration distribution of at least one of the Group III atom and the Group VI atom, in the light absorbing layer.

12. The solar cell according to claim 9, wherein a concentration the Group VI atom is higher in the first region and in the second region than in the third region of the light absorbing layer.

13. The solar cell according to claim 9, wherein a concentration of the Group III atom varies by less than 10%, throughout the light absorbing layer.

14. The solar cell according to claim 1, wherein the light absorbing layer comprises a compound of chemical formula Cu(InₓGa₁₋ₓ)(Se_{y}S_{1-y}).

15. A method of preparing a solar cell, the method comprising:
forming a first electrode on a substrate;
forming a light absorbing layer on the first electrode; and
forming a buffer layer on the light absorbing layer;
wherein the forming of the light absorbing layer comprises:
forming a precursor layer on the first electrode, the precursor layer comprising Cu, Ga, and In,
performing a first heat treatment on the precursor layer with a Se-containing gas to form a Cu(InₓGa₁₋ₓ)Se₂ layer, and
performing a second heat treatment on the Cu(InₓGa₁₋ₓ)Se₂ layer with a S-containing gas to form a Cu(InₓGa₁₋ₓ)(Se_{y}S_{1-y}) layer, to provide the light absorbing layer.

16. The method according to claim 15, further comprising:
forming a second electrode layer on the buffer layer; or
forming a second electrode layer on the buffer layer and forming an anti-reflection layer on the second electrode layer.

17. The method according to claim 15, wherein the forming of the precursor layer comprises:
forming a Cu—Ga—In layer on the first electrode layer; or
forming a Cu—Ga layer on the first electrode layer and then forming an In layer on the Cu—Ga layer.

18. The method according to claim 15, wherein the forming of the precursor layer comprises:
sputtering with a Cu—Ga—In alloy as a target material; or
sputtering with a Cu—Ga alloy as a target material and sputtering with an In-based material as a target material.

19. The method according to claim 15, wherein the first heat treatment is performed at a temperature from about 300° C. to about 500° C. for a period of time from about 5 minutes to about 40 minutes.

20. The method according to claim 15, wherein the second heat treatment is performed at a temperature from about 500° C. to about 700° C. for a period of time from about 10 minutes to about 100 minutes.
